(19) United States
(12) Patent Application Publication
(10) Pub. No.: US 2025/0169050 A1
(43) Pub. Date: May 22, 2025

(54) SECOND-LEVEL METALLIZATION TESTABLE FULLY INTEGRATED AND MULTI-FUNCTIONAL STATIC RANDOM ACCESS MEMORY AND SCANNABLE LATCHES

(71) Applicant: International Business Machines Corporation, Armonk, NY (US)

(72) Inventors: Rajiv Joshi, Yorktown Heights, NY (US); Sam Storino, Pompano Beach, FL (US); Christopher Gerard Murphy, Red Hook, NY (US); Shirin Akter, Irvine, CA (US); Ishtiaq Ahsan, Halfmoon, NY (US); Leon Sigal, Monsey, NY (US)

(21) Appl. No.: 18/512,140

(22) Filed: Nov. 17, 2023

(51) Int. Cl. H10B 10/00; H01L 21/66

(52) U.S. Cl. CPC H10B 10/18; H01L 22/20

(57) ABSTRACT

A static random access memory (SRAM) structure is provided and includes a wafer including a first metallization (M1) layer and a second metallization (M2) layer on which the M1 layer is disposed and a fully functional SRAM cell including circuitry using a maximum of two of the M1 layer and the M2 layer.

### BACKGROUND

The present invention generally relates to semiconductor devices. More specifically, the present invention relates to a second-level metallization (M2) testable fully integrated and multi-functional static random access memory (SRAM) and scannable latches.

SRAM is a type of RAM that uses latching circuitry (i.e., flip-flops) to store bits. SRAM can be characterized as volatile memory in that data is lost when power is removed. The term “static” differentiates SRAM from other types of RAM since SRAM will hold its data permanently in the presence of power, while data in other types, such as dynamic RAM (DRAM), decays and must be periodically refreshed. SRAM is typically used for cache and internal registers of a central processing unit (CPU).

### SUMMARY

According to an aspect of the invention a static random access memory (SRAM) structure is provided. A non-limiting example of the SRAM structure includes a wafer including a first metallization (M1) layer and a second metallization (M2) layer on which the M1 layer is disposed and a fully functional SRAM cell including circuitry using a maximum of the M1 layer and the M2 layer. Additionally or alternatively, the SRAM structure provides for a functional scan chain/SRAM technology yield learning macro that is testable at a much earlier process step (Metal2 or M2) than the traditional process step (Metal8 or M8).

According to an aspect of the invention a static random access memory (SRAM) structure is provided. A non-limiting example of the SRAM structure includes a wafer including a first metallization (M1) layer, a second metallization (M2) layer on which the M1 layer is disposed and multiple additional metallization layers on or over which the M2 layer is disposed and a fully functional SRAM cell including circuitry using only the M1 layer and the M2 layer. Additionally or alternatively, the SRAM structure provides for a functional scan chain/SRAM technology yield learning macro that is testable at a much earlier process step (Metal2 or M2) than the traditional process step (Metal8 or M8).

According to an aspect of the invention a static random access memory (SRAM) structure is provided. A non-limiting example of the SRAM structure includes a wafer including a first metallization (M1) layer, a second metallization (M2) layer on which the first M1 layer is disposed and multiple additional metallization layers on or over which which the M2 layer is disposed and a fully functional SRAM cell including word line and bit line circuitry limited to the M1 layer and the M2 layer and power distribution circuitry limited to the M2 layer. Additionally or alternatively, the SRAM structure provides for a functional scan chain/SRAM technology yield learning macro that is testable at a much earlier process step (Metal2 or M2) than the traditional process step (Metal8 or M8).

According to an aspect of the invention, a method of static random access memory (SRAM) structure processing is provided. A non-limiting example of the method includes processing a wafer to comprise a first metallization (M1) layer and a second metallization (M2) layer on which the M1 layer is disposed, assembling a fully functional SRAM cell including word line and bit line circuitry limited to the M1 layer and the M2 layer, power distribution circuitry limited to the M2 layer and SRAM circuitry, a peripheral circuit and a logic circuit limited to the M1 layer and the M2 layer, testing the SRAM cell to determine whether a yield of the processing and the assembling exceeds a threshold and executing failure analysis of the SRAM cell when the yield does not exceed the threshold and iteratively repeating the processing and the assembling. Additionally or alternatively, the method provides for testing of a functional scan chain/SRAM technology yield learning macro at a much earlier process step (Metal2 or M2) than the traditional process step (Metal8 or M8).

According to an aspect of the invention, a static random access memory (SRAM) structure testing method is provided. A non-limiting example of the method includes forming an initial SRAM cell in first and second metallization (M1 and M2) layers, determining, from results of a test of the initial SRAM cell, whether an initial yield exceeds a first threshold, executing failure analysis of the initial SRAM cell when the initial yield does not exceed the first threshold and iteratively restarting the method and completing formation of a final SRAM cell in the M1 layer and the M2 layer and in additional metallization layers of a wafer when the initial yield exceeds the first threshold. Additionally or alternatively, the method provides for testing of a functional scan chain/SRAM technology yield learning macro at a much earlier process step (Metal2 or M2) than the traditional process step (Metal8 or M8).

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a schematic diagram illustrating an SRAM structure in accordance with one or more embodiments of the present invention;

FIGS. 2A and 2B are schematic diagrams illustrating an SRAM cell in accordance with one or more embodiments of the present invention;

FIG. 3 is a flow diagram illustrating a method of SRAM structure processing in accordance with one or more embodiments of the present invention;

FIG. 4 is a flow diagram illustrating an SRAM structure testing method in accordance with one or more embodiments of the present invention; and

FIG. 5 is a top-down view of an SRAM structure in which power and signal lines at high metallization levels are used in accordance with one or more embodiments of the present invention.

The diagrams depicted herein are illustrative. There can be many variations to the diagram, or the operations described therein without departing from the spirit of the invention. For instance, the actions can be performed in a differing order or actions can be added, deleted, or modified. Also, the term “coupled” and variations thereof describes having a communications path between two elements and does not imply a direct connection between the elements with no intervening elements/connections between them. All these variations are considered a part of the specification.

In the accompanying figures and following detailed description of the described embodiments, the various elements illustrated in the figures are provided with two- or three-digit reference numbers. With minor exceptions, the leftmost digit(s) of each reference number corresponds to the figure in which its element is first illustrated.

### DETAILED DESCRIPTION

According to an aspect of the invention a static random access memory (SRAM) structure is provided. A non-limiting example of the SRAM structure includes a wafer including a first metallization (M1) layer and a second metallization (M2) layer on which the M1 layer is disposed and a fully functional SRAM cell including circuitry using a maximum of two of the M1 layer and the M2 layer. Additionally or alternatively, the SRAM structure provides for a functional scan chain/SRAM technology yield learning macro that is testable at a much earlier process step (Metal2 or M2) than the traditional process step (Metal8 or M8).

In embodiments, the SRAM cell includes SRAM circuitry, a peripheral circuit and a logic circuit using the maximum of the two of the M1 layer and the M2 layer. The SRAM structure thus includes a functional SRAM cell.

In embodiments, the circuitry word line and bit line circuitry limited to the M1 layer and the M2 layer and power distribution circuitry limited to the M2 layer. This allows for the power distribution circuitry to be positioned close to the SRAM cell.

In embodiments, the word line and bit line circuitry are spread horizontally outwardly from the SRAM cell. This further allows for the power distribution circuitry to be positioned close to the SRAM cell.

In embodiments, bit lines of the bit line circuitry are oriented vertically on the M1 layer and word lines of the word line circuitry are limited to the M2 layer. This further allows for the power distribution circuitry to be positioned close to the SRAM cell.

In embodiments, the power distribution circuitry is disposed proximate to the SRAM cell. This further allows for the power distribution circuitry to be positioned close to the SRAM cell.

In embodiments, an output of the SRAM cell is routed locally on the M1 layer and then routed to the M2 layer. This allows the SRAM cell to be tested at the M2 level.

According to an aspect of the invention a static random access memory (SRAM) structure is provided. A non-limiting example of the SRAM structure includes a wafer including a first metallization (M1) layer, a second metallization (M2) layer on which the M1 layer is disposed and multiple additional metallization layers on or over which the M2 layer is disposed and a fully functional SRAM cell including circuitry using only the M1 layer and the M2 layer. Additionally or alternatively, the SRAM structure provides for a functional scan chain/SRAM technology yield learning macro that is testable at a much earlier process step (Metal2 or M2) than the traditional process step (Metal8 or M8).

In embodiments, the SRAM cell includes SRAM circuitry, a peripheral circuit and a logic circuit using the maximum of the two of the M1 layer and the M2 layer and the multiple additional metallization layers. The SRAM structure thus includes a functional SRAM cell.

In embodiments, the circuitry word line and bit line circuitry limited to the M1 layer and the M2 layer and power distribution circuitry limited to the M2 layer. This allows for the power distribution circuitry to be positioned close to the SRAM cell.

In embodiments, the word line and bit line circuitry are spread horizontally outwardly from the SRAM cell. This further allows for the power distribution circuitry to be positioned close to the SRAM cell.

In embodiments, bit lines of the bit line circuitry are oriented vertically on the M1 layer and word lines of the word line circuitry are limited to the M2 layer. This further allows for the power distribution circuitry to be positioned close to the SRAM cell.

In embodiments, the power distribution circuitry is disposed proximate to the SRAM cell. This further allows for the power distribution circuitry to be positioned close to the SRAM cell.

In embodiments, an output of the SRAM cell is routed locally on the M1 layer and then routed to the M2 layer. This allows the SRAM cell to be tested at the M2 level.

According to an aspect of the invention a static random access memory (SRAM) structure is provided. A non-limiting example of the SRAM structure includes a wafer including a first metallization (M1) layer, a second metallization (M2) layer on which the M1 layer is disposed and multiple additional metallization layers on or over which the M2 layer is disposed and a fully functional SRAM cell including word line and bit line circuitry limited to the M1 layer and the M2 layer and power distribution circuitry limited to the M2 layer. Additionally or alternatively, the SRAM structure provides for a functional scan chain/SRAM technology yield learning macro that is testable at a much earlier process step (Metal2 or M2) than the traditional process step (Metal8 or M8).

In embodiments, the SRAM cell includes SRAM circuitry, a peripheral circuit and a logic circuit using the maximum of the two of the M1 layer and the M2 layer and the multiple additional metallization layers. The SRAM structure thus includes a functional SRAM cell.

In embodiments, the circuitry word line and bit line circuitry limited to the M1 layer and the M2 layer and power distribution circuitry limited to the M2 layer. This allows for the power distribution circuitry to be positioned close to the SRAM cell.

In embodiments, the word line and bit line circuitry are spread horizontally outwardly from the SRAM cell. This further allows for the power distribution circuitry to be positioned close to the SRAM cell.

In embodiments, bit lines of the bit line circuitry are oriented vertically on the M1 layer and word lines of the word line circuitry are limited to the M2 layer. This further allows for the power distribution circuitry to be positioned close to the SRAM cell.

In embodiments, the power distribution circuitry is disposed proximate to the SRAM cell. This further allows for the power distribution circuitry to be positioned close to the SRAM cell.

In embodiments, an output of the SRAM cell is routed locally on the M1 layer and then routed to the M2 layer. This allows the SRAM cell to be tested at the M2 level.

According to an aspect of the invention, a method of static random access memory (SRAM) structure processing is provided. A non-limiting example of the method includes processing a wafer to comprise a first metallization (M1) layer and a second metallization (M2) layer on which the M1 layer is disposed, assembling a fully functional SRAM cell including word line and bit line circuitry limited to the M1 layer and the M2 layer, power distribution circuitry limited to the M2 layer and SRAM circuitry, a peripheral circuit and a logic circuit limited to the M1 layer and the M2 layer, testing the SRAM cell to determine whether a yield of the processing and the assembling exceeds a threshold and executing failure analysis of the SRAM cell when the yield does not exceed the threshold and iteratively repeating the processing and the assembling. Additionally or alternatively, the method provides for testing of a functional scan chain/SRAM technology yield learning macro at a much earlier process step (Metal2 or M2) than the traditional process step (Metal8 or M8).

According to an aspect of the invention, a static random access memory (SRAM) structure testing method is provided. A non-limiting example of the method includes forming an initial SRAM cell in first and second metallization (M1 and M2) layers, determining, from results of a test of the initial SRAM cell, whether an initial yield exceeds a first threshold, executing failure analysis of the initial SRAM cell when the initial yield does not exceed the first threshold and iteratively restarting the method and completing formation of a final SRAM cell in the M1 layer and the M2 layer and in additional metallization layers of a wafer when the initial yield exceeds the first threshold. Additionally or alternatively, the method provides for testing of a functional scan chain/SRAM technology yield learning macro at a much earlier process step (Metal2 or M2) than the traditional process step (Metal8 or M8).

In embodiments, the method includes determining, from results of a test of a final SRAM cell, whether a final yield exceeds a second threshold, executing failure analysis of the final SRAM cell when the final yield does not exceed the second threshold and iteratively restarting the method and completing the method as a process-of-record (POR) when the final yield exceeds the second threshold. This provides for a way to complete final SRAM processing.

In embodiments, the second threshold is a multiple of the first threshold. This provides for a predefined threshold for the final yield.

In embodiments, the method includes forming structures of the final SRAM cell in the additional metallization layers in parallel with at least the determining and the executing. This allows certain processing of the method to be executed early in the total process to save time.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, SRAM line monitors are crucial for developing line processes, evaluating functionality and yield. However, current SRAM extends through three to four levels of metallization due to wiring congestion prevention integration and this multi-level back-end-of-line (BEOL) processing makes building a complicated SRAM and generate learning difficult in a short duration.

That is, in early technology development phases, processing wafers through various process stages to a high enough metal level so that traditional functional macros can be tested can require significant amounts of time. This can be due to the need to process metal layers two through 8 (M2 through M8). A result of the time requirement is that there can be a corresponding loss of valuable time in yield learning cycles. The loss of valuable time in yield learning cycles can accumulate over time with each subsequent learning cycle due to feedback from, e.g., M8 functional test data, being required for subsequent process improvements.

Turning now to an overview of the aspects of the invention, one or more embodiments of the invention address the above-described shortcomings of the prior art by providing an SRAM structure that includes a wafer and a fully functional SRAM cell.

The wafer includes a first metallization (M1) layer, a second metallization (M2) layer on which the M1 layer is disposed and multiple additional metallization layers (such as an M3 layer) on or over which the M2 layer is disposed. The SRAM cell includes circuitry that uses only the M1 layer and the M2 layer, with power and ground possibly on M3.

The above-described aspects of the invention address the shortcomings of the prior art by providing for the utilization of a maximum of two levels of metal to fabricate in-line SRAM which can be tested with a quick turnaround time. Also, there is a provision of multi-functionality, such as read/write assist, I-V characteristics to identify functionality and improved yield issues as well as a unique layout design that accommodates input/output (I/O) signals as well as power and ground signals.

In greater detail, one or more embodiments of the present invention provide for a functional scan chain/SRAM technology yield learning macro that is testable at a much earlier process step (Metal2 or M2) than the traditional process step (Metal8 or M8). In conventional designs, scan chain integrated circuits are designed for high density and require power and ground signals to be run at higher metal levels since they have wider dimensions/lower resistivity and therefore less voltage drop. This makes the circuit operational/testable only at a high metal level (e.g., at M7 or M8, etc.). As will be described below, a compromise is made on densities of front-end-of-line (FEOL)/middle-of-line (MOL) level designs which limits IR voltage drops through thin metal lines at the M1 layer and the M2 layer since the power to only a small block of the circuit is fed by these M1 and M2 lines. Also, by bringing probe pads very close to circuit blocks and having a slender, thin aspect ratio of the circuit blocks, it is possible to further limit IR drops.

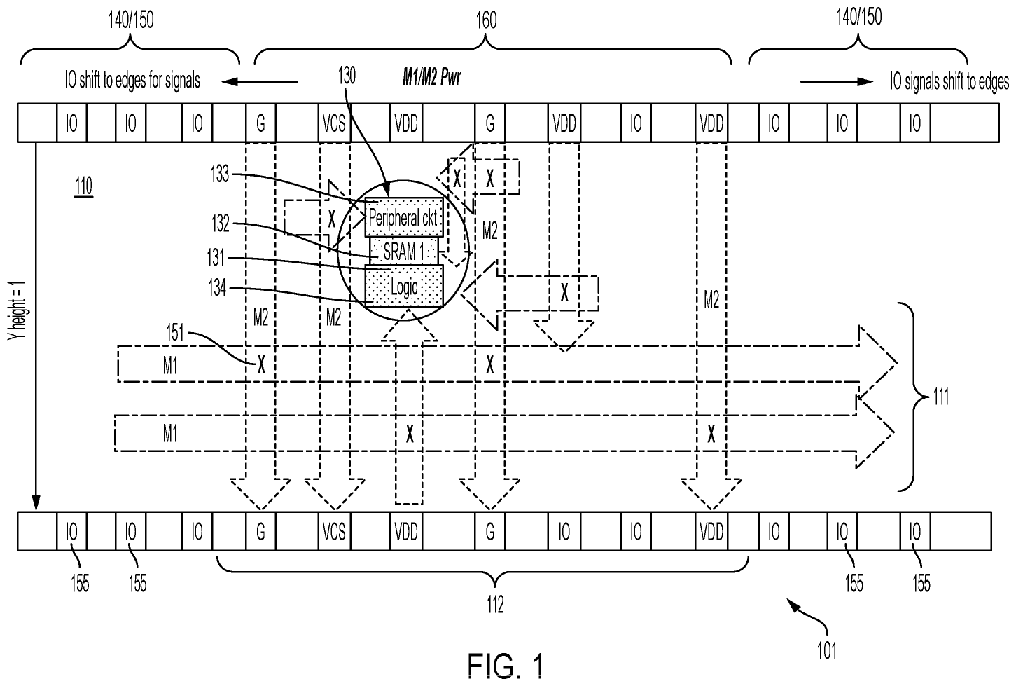

Turning now to a more detailed description of aspects of the present invention, FIG. 1 is a top-down view of an SRAM structure 101. The SRAM structure 101 includes a wafer 110 and a fully functional SRAM cell (hereinafter referred to as “the SRAM cell”) 130. The wafer 110 includes a first metallization (M1) layer 111, a second metallization (M2) layer 112 on which the M1 layer 111 is disposed, and multiple additional metallization layers on or over which the M2 layer 112 is disposed. The SRAM cell 130 includes circuitry 131 that uses only the M1 layer 111 and the M2 layer 112 (in some cases, the circuitry 131 can use a maximum of two of the M1 layer 111 and the M2 layer 112 and the multiple additional metallization layers; for purposes of clarity and brevity, however, the following description will relate to the case in which the circuitry 131 uses only the M1 layer 111 and the M2 layer 112). The SRAM cell 130 further includes SRAM circuitry 132, a peripheral circuit 133 and a logic circuit 134 using only the M1 layer 111 and the M2 layer 112.

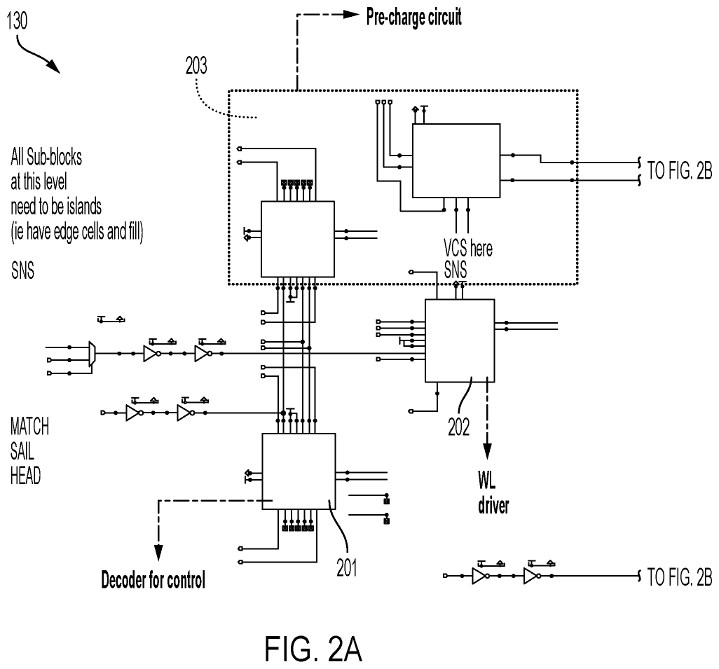

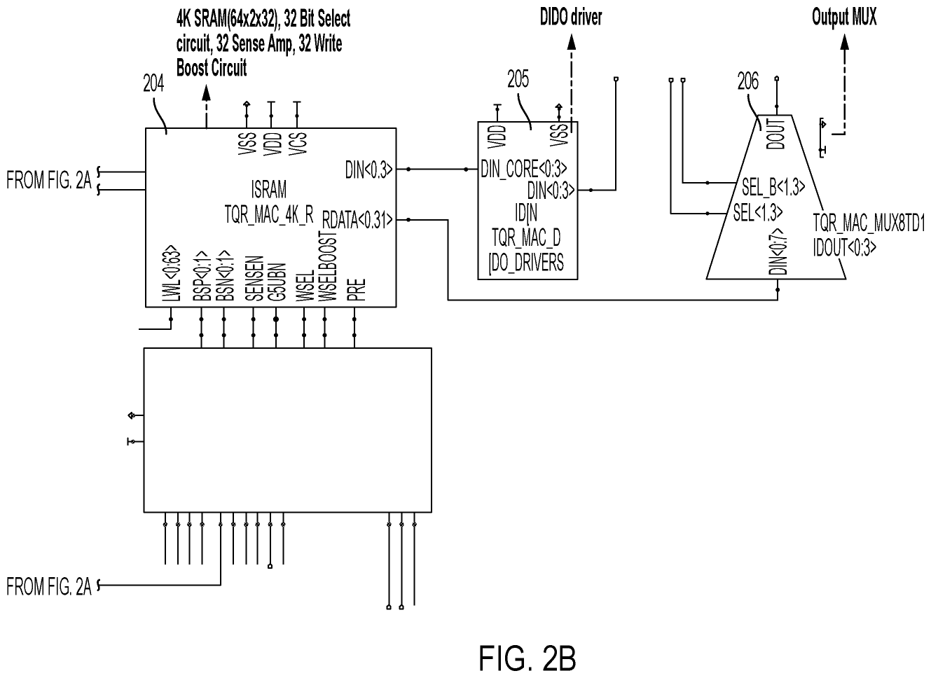

With reference to FIGS. 2A and 2B, in greater detail, the SRAM cell 130 of FIG. 1 can include a decoder 201, a word line (WL) driver 202, a pre-charge circuit 203, an SRAM circuit 204, a data in/data out (DIDO) driver 205 and an output mux 206 to multiplex outgoing signals.

With continued reference to FIG. 1 and FIGS. 2A and 2B, the circuitry 131 includes word line circuitry 140, bit line circuitry 150 and power distribution circuitry 160. The word line circuitry 140 and the bit line circuitry 150 are limited to the M1 layer 111 and the M2 layer 112 as evidenced by the input/output (I/O) terminals 155 shown in FIG. 1 with which the word line circuitry 140 and the bit line circuitry 150 are connectable. The power distribution circuitry 160 is limited to the M2 layer 112 and includes a ground signal G and voltage supply signals VCS and VDD. As shown in FIG. 1, the power distribution circuitry 160 is generally centered around the SRAM cell 130 and the word line circuitry 140 and the bit line circuitry 150 is spread out horizontally outwardly from the SRAM cell 130. In particular, the I/O terminals for the word line circuitry 140 and the bit line circuitry 150 can be shifted outwardly from the SRAM cell 130 and toward the edges of the M1 layer 111 and the M2 layer 112 whereas the power distribution circuitry 160 remains generally centered around and proximate to (as compared to the word line circuitry 140 and the bit line circuitry 150) the SRAM cell 130.

In accordance with one or more embodiments of the present invention, the bit line circuitry 150 can include vertically oriented bit lines 151 that extend between the M1 layer 111 and the M2 layer 112 whereas the word line circuitry 140 can include word lines that are limited to the M2 layer. In some, but not all cases, the output of the SRAM cell 130 can be routed locally on the M1 layer 111 and then routed to the M2 layer 112.

In accordance with one or more further embodiments of the present invention, at least one of the word line circuitry 140, the bit line circuitry 150, and the power distribution circuitry 160 in the M1 layer 111 and in the M2 layer 112 can be provided with fat metal wiring, which is two or more times the width of normal metal wiring.

In some cases, the SRAM structure 101 can include read/write assist circuitry. Read/write assist circuitry can be provided to help in stability improvement and write-ability of the SRAM cell 130. A stability circuit can increase the slew of a word line, which effectively slows down charge leakage from a bit line to a cell. Write assist circuit, when invoked, pulls down the bitline on “0” and thus helps to write to the cell effectively.

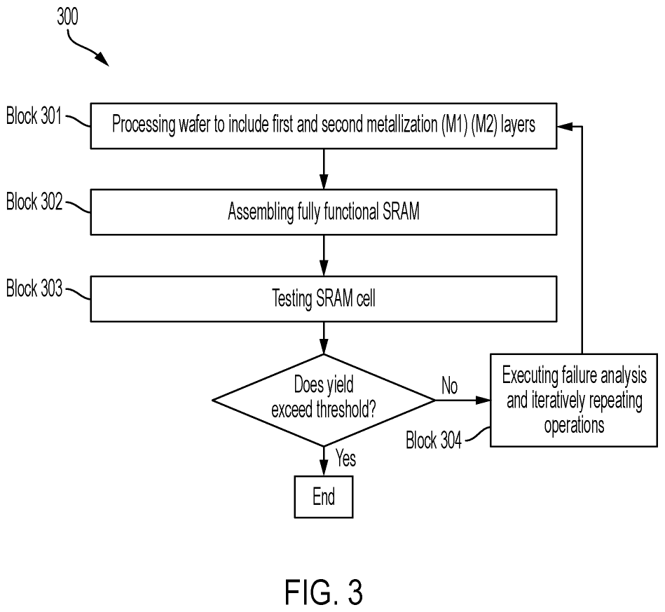

With reference to FIG. 3, a method 300 of SRAM structure processing is provided to arrive at, for example, the SRAM structure 101 of FIG. 1 and the SRAM cell 130 of FIGS. 2A and 2B. As shown in FIG. 3, the method 300 includes processing a wafer to include a first metallization (M1) layer and a second metallization (M2) layer on which the M1 layer is disposed (block 301) and assembling a fully functional SRAM cell including word line and bit line circuitry limited to the M1 layer and the M2 layer, power distribution circuitry limited to the M2 layer and SRAM circuitry, a peripheral circuit and a logic circuit limited to the M1 layer and the M2 layer (block 302). The method 300 then includes testing the SRAM cell to determine whether the yield of the processing and the assembling exceeds a threshold (block 303) and executing failure analysis of the SRAM cell in the event the yield does not exceed the threshold and iteratively repeating the processing and the assembling (block 304). In this way, an ability to test for yield of block 303 and to execute failure analysis of block 304 with the M1 layer and the M2 layer processed and assembled allows for a tight feedback loop that enhances productivity and saves processing costs. When the yield does match or exceed the threshold, the method 300 ends.

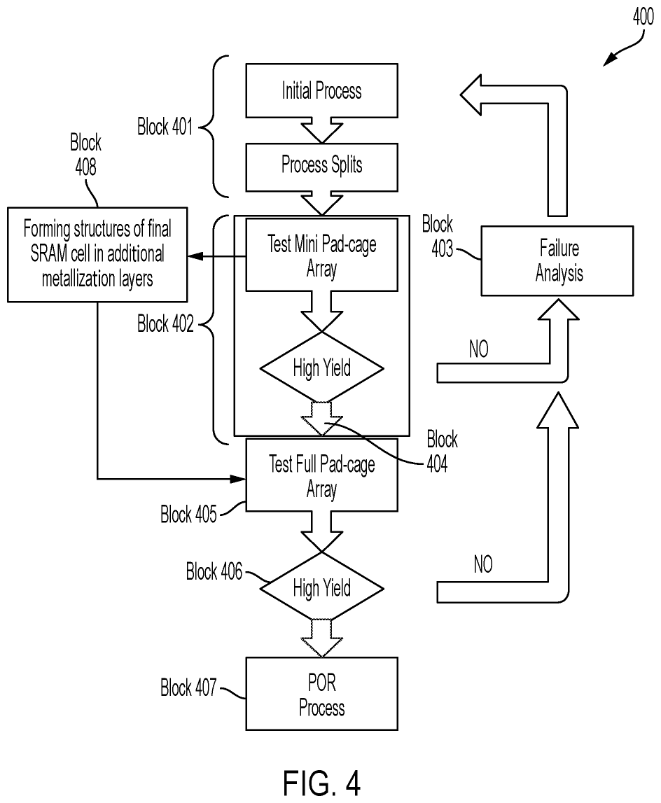

With reference to FIG. 4, an SRAM structure testing method 400 is provided for use with the SRAM structure 101 of FIG. 1 and the SRAM cell 130 of FIGS. 2A and 2B. As shown in FIG. 4, the method 400 initially includes forming an initial SRAM cell in first and second metallization (M1 and M2) layers (block 401). In block 401, the “initial process” can include base processes carried over from earlier experience. The “process splits” refer to cases in which different lots are treated differently. For example, in some lots, voltages can be varied between high, medium and low. In other lots, widths of circuit traces and/or back end widths can be varied. In any case, the use of different variables can lead to different process corners. As is also shown in FIG. 4, the method 400 further includes determining, from results of a test of the initial SRAM cell, whether an initial yield exceeds a first threshold (block 402), executing failure analysis of the initial SRAM cell when the initial yield does not exceed the first threshold and iteratively restarting the method (block 403) and completing formation of a final SRAM cell in the M1 layer and the M2 layer and in additional metallization layers of the wafer when the initial yield exceeds the first threshold (block 404). In accordance with one or more embodiments of the present invention, the method 400 can further include wide-level and full wafer iterations including determining, from results of a test of the final SRAM cell, whether a final yield exceeds a second threshold (block 405), executing failure analysis of the final SRAM cell when the final yield does not exceed the second threshold and iteratively restarting the method (block 406) and completing the method as a process-of-record (POR) when the final yield exceeds the second threshold (block 407). In some but not all cases, the second threshold can be a multiple or a square of the first threshold.

In accordance with further embodiments, the SRAM structure testing method 400 can further include forming structures of the final SRAM cell in the additional metallization layers in parallel with at least the determining and the executing of blocks 402 and 403 (block 408). This can be done under various conditions of the SRAM structure testing method 400 including, but not limited to, cases in which the parallel processing (i.e., the forming of the structures of block 408) will not interfere with the determining and the executing of blocks 402 and 403 and/or where it can be determined that the parallel processing will not otherwise or unnecessarily impede the use of limited resources, such as those cases in which it is likely that the determining of block 402 will indicate that the initial yield will be matches or exceeded. In any case, the parallel processing can lead to a more robust SRAM cell and shorten a total time of the completing of the formation of the final SRAM cell in the M1 layer and the M2 layer and in the additional metallization layers of block 404.

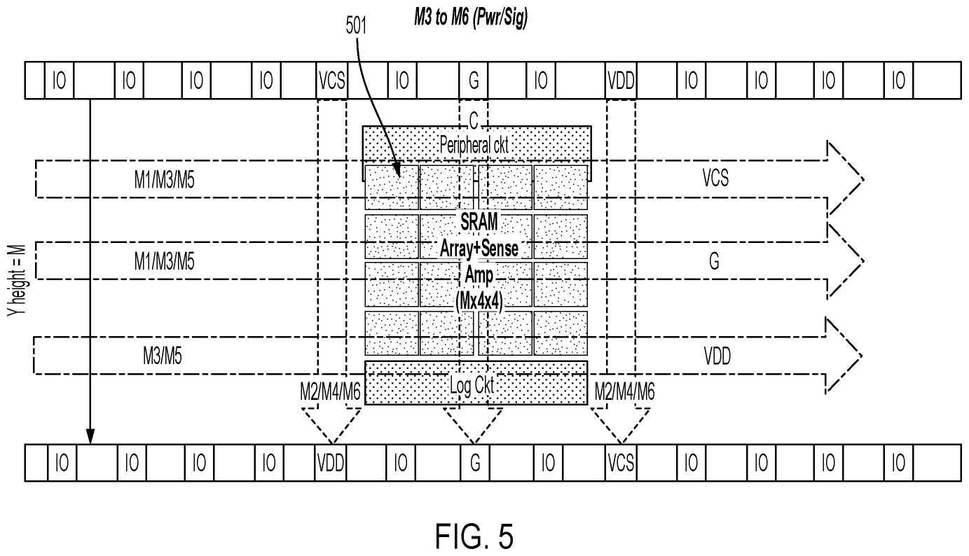

With continued reference to FIG. 4 and with additional reference to FIG. 5, the SRAM cell 130 of FIG. 1 and FIGS. 2A and 2B can be provided as a macro 501 that is measured at the M2 level as described above. If, based on the measurements of the macro 501 at the M2 level, it is found that the yield of the macro is sufficient, it can be determined that the macro can be metallized further at higher metallization levels (i.e., M3-M6). The details of FIG. 5 illustrate that, in cases in which the macro can be metallized at the higher metallization levels, this can be achieved by connections of power and signal lines at the higher metallization levels at which robustness of those power and signal lines can be improved due to lower resistance wiring at these metallization levels.

In accordance with one or more embodiments of the present invention, for the determining of whether the initial yield exceeds the first threshold from results of the test of the initial SRAM cell of block 402, the initial SRAM cell can be provided as a functional macro for scannable latches at the M2 level. A functional macro in this case can be made of long chain of scannable latches that can be up to thousands of scannable latches long. The testing involves testing these long chains of scannable latches to evaluate the yield. If the yield of the long chains of scannable latches is high (i.e., exceeds the first threshold), the process and design are robust and metallization at higher levels can proceed.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100}orientated crystalline surface can take on a {100}orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A static random access memory (SRAM) structure, comprising:
a wafer comprising a first metallization (M1) layer and a second metallization (M2) layer on which the M1 layer is disposed; and
a fully functional SRAM cell comprising circuitry using a maximum of the M1 layer and the M2 layer.

2. The SRAM structure according to claim 1, wherein the SRAM cell comprises SRAM circuitry, a peripheral circuit and a logic circuit using the maximum of the M1 layer and the M2 layer.

3. The SRAM structure according to claim 1, wherein the circuitry comprises:
word line and bit line circuitry limited to the M1 layer and the M2 layer; and
power distribution circuitry limited to the M2 layer.

4. The SRAM structure according to claim 3, wherein the word line and bit line circuitry are spread horizontally outwardly from the SRAM cell.

5. The SRAM structure according to claim 4, wherein bit lines of the bit line circuitry are oriented vertically on the M1 layer and word lines of the word line circuitry are limited to the M2 layer.

6. The SRAM structure according to claim 3, wherein the power distribution circuitry is disposed proximate to the SRAM cell.

7. The SRAM structure according to claim 1, wherein an output of the SRAM cell is routed locally on the M1 layer and then routed to the M2 layer.

8. A static random access memory (SRAM) structure, comprising:
a wafer comprising a first metallization (M1) layer, a second metallization (M2) layer on which the M1 layer is disposed and multiple additional metallization layers on or over which the M2 layer is disposed; and
a fully functional SRAM cell comprising circuitry using only the M1 layer and the M2 layer.

9. The SRAM structure according to claim 8, wherein the SRAM cell comprises SRAM circuitry, a peripheral circuit and a logic circuit using only the M1 layer and the M2 layer.

10. The SRAM structure according to claim 8, wherein the circuitry comprises:
word line and bit line circuitry limited to the M1 layer and the M2 layer; and
power distribution circuitry limited to the M2 layer.

11. The SRAM structure according to claim 10, wherein the word line and bit line circuitry are spread horizontally outwardly from the SRAM cell.

12. The SRAM structure according to claim 11, wherein bit lines of the bit line circuitry are oriented vertically on the M1 layer and word lines of the word line circuitry are limited to the M2 layer.

13. The SRAM structure according to claim 10, wherein the power distribution circuitry is disposed proximate to the SRAM cell.

14. The SRAM structure according to claim 8, wherein an output of the SRAM cell is routed locally on the M1 layer and then routed to the M2 layer.

15. A static random access memory (SRAM) structure, comprising:
a wafer comprising a first metallization (M1) layer, a second metallization (M2) layer on which the M1 layer is disposed and multiple additional metallization layers on or over which the M2 layer is disposed; and
a fully functional SRAM cell comprising:
word line and bit line circuitry limited to the M1 layer and the M2 layer; and
power distribution circuitry limited to the M2 layer.

16. The SRAM structure according to claim 15, wherein the SRAM cell comprises SRAM circuitry, a peripheral circuit and a logic circuit limited to the M1 layer and the M2 layer.

17. The SRAM structure according to claim 15, wherein the word line and bit line circuitry are spread horizontally outwardly from the SRAM cell.

18. The SRAM structure according to claim 17, wherein bit lines of the bit line circuitry are oriented vertically on the M1 layer and word lines of the word line circuitry are limited to the M2 layer.

19. The SRAM structure according to claim 15, wherein the power distribution circuitry is disposed proximate to the SRAM cell.

20. The SRAM structure according to claim 15, wherein an output of the SRAM cell is routed locally on the M1 layer and then routed to the M2 layer.

21. A method of static random access memory (SRAM) structure processing, the method comprising:
processing a wafer to comprise a first metallization (M1) layer and a second metallization (M2) layer on which the M1 layer is disposed;
assembling a fully functional SRAM cell comprising word line and bit line circuitry limited to the M1 layer and the M2 layer, power distribution circuitry limited to the M2 layer and SRAM circuitry, a peripheral circuit and a logic circuit limited to the M1 layer and the M2 layer;
testing the SRAM cell to determine whether a yield of the processing and the assembling exceeds a threshold; and
executing failure analysis of the SRAM cell when the yield does not exceed the threshold and iteratively repeating the processing and the assembling.

22. A static random access memory (SRAM) structure testing method, comprising:
forming an initial SRAM cell in first and second metallization (M1 and M2) layers;
determining, from results of a test of the initial SRAM cell, whether an initial yield exceeds a first threshold;
executing failure analysis of the initial SRAM cell when the initial yield does not exceed the first threshold and iteratively restarting the method; and
completing formation of a final SRAM cell in the M1 layer and the M2 layer and in additional metallization layers of a wafer when the initial yield exceeds the first threshold.

23. The method according to claim 21, further comprising:
determining, from results of a test of a final SRAM cell, whether a final yield exceeds a second threshold;
executing failure analysis of the final SRAM cell when the final yield does not exceed the second threshold and iteratively restarting the method; and
completing the method as a process-of-record (POR) when the final yield exceeds the second threshold.

24. The method according to claim 23, wherein the second threshold is a multiple of the first threshold.

25. The method according to claim 21, further comprising forming structures of the final SRAM cell in the additional metallization layers in parallel with at least the determining and the executing.
